(19) United States
(12) Patent Application Publication
(10) Pub. No.: US 2007/0215407 A1
(43) Pub. Date: Sep. 20, 2007

(54) Loudspeaker device

(76) Inventor: Kun-Tien Chiang, Tainan Hsien (TW)

Correspondence Address: OSTROLENK FABER GERB & SOFFEN, 1180 AVENUE OF THE AMERICAS, NEW YORK, NY, 100368403, US

(21) Appl. No.: 11/384,675

(22) Filed: Mar. 20, 2006

(51) Int. Cl. H05K 5/00; A47B 81/06

(52) U.S. Cl. 181/156; 181/199

(57) ABSTRACT

A loudspeaker device includes an enclosure, a loudspeaker mechanism acoustically mounted in the enclosure for radiating sound, and a sound guide mounted in the enclosure. The sound guide includes a sound-collecting cover that covers a back side of the loudspeaker mechanism, and a sound duct having a first end in spatial communication with the sound-collecting cover, and a second end connected to the enclosure and in spatial communication with an exterior of the enclosure.

### BACKGROUND OF THE INVENTION

1. Field of the Invention

The invention relates to a sound-radiating device, more particularly to a loudspeaker device.

2. Description of the Related Art

As shown in FIG. 1, a conventional loudspeaker device includes an enclosure 11 and a loudspeaker mechanism 12 acoustically mounted in the enclosure 11 for radiating sound. When the loudspeaker mechanism 12 is driven by audio signals from an external signal source (not shown), a cone 121 of the loudspeaker mechanism 12 vibrates to produce sound waves that are transmitted forwardly. However, back waves are also generated in the enclosure 11 when the cone 121 of the loudspeaker mechanism 12 vibrates. The back waves in the enclosure 11 can interfere with the vibration of the cone 121, thereby affecting adversely sound output quality.

As a solution to the above drawback, it has been proposed heretofore to line the interior of the enclosure 11 with a sound-absorbing material 13, such as foam, for back wave attenuation. Nevertheless, higher manufacturing costs are incurred in view of the additional cost for the sound-absorbing material 13 and the relatively complicated installation process for the same.

### SUMMARY OF THE INVENTION

Therefore, the object of the present invention is to provide a loudspeaker device that can prevent back wave interference and that can be fabricated at a lower cost.

Accordingly, a loudspeaker device of the present invention comprises an enclosure, a loudspeaker mechanism acoustically mounted in the enclosure for radiating sound, and a sound guide mounted in the enclosure. The sound guide includes a sound-collecting cover that covers a back side of the loudspeaker mechanism, and a sound duct having a first end in spatial communication with the sound-collecting cover, and a second end connected to the enclosure and in spatial communication with an exterior of the enclosure.

### BRIEF DESCRIPTION OF THE DRAWINGS

Other features and advantages of the present invention will become apparent in the following detailed description of the preferred embodiments with reference to the accompanying drawings, of which:

FIG. 1 is a schematic partly sectional view of a conventional loudspeaker device;

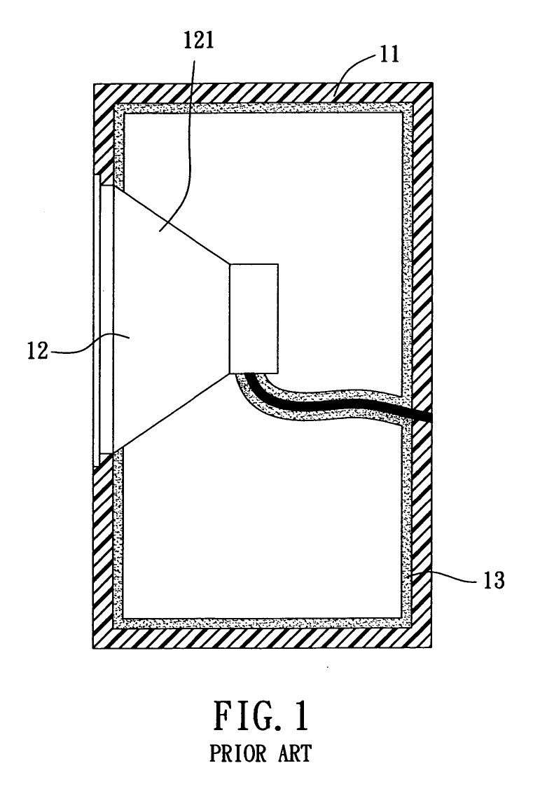

FIG. 2 is an assembled perspective view of the first preferred embodiment of a loudspeaker device according to the present invention;

FIG. 3 is a schematic partly sectional view of the first preferred embodiment; and

FIG. 4 is a schematic partly sectional view of the second preferred embodiment of a loudspeaker device according to the present invention.

### DETAILED DESCRIPTION OF THE PREFERRED EMBODIMENTS

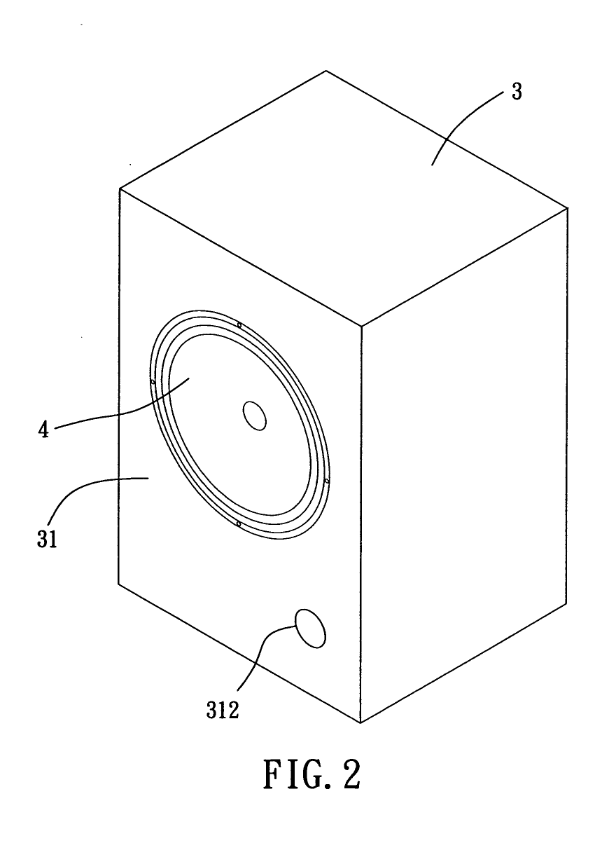

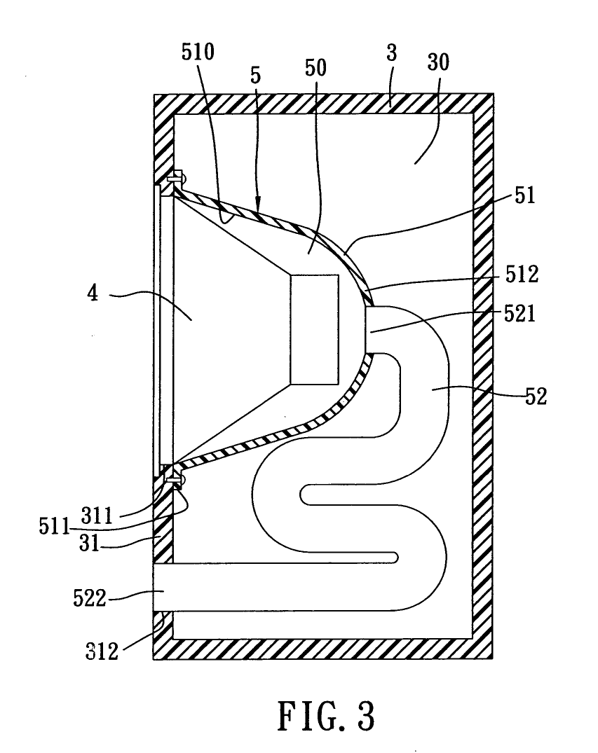

Referring to FIGS. 2 and 3, the first preferred embodiment of a loudspeaker device according to the present invention is shown to comprise an enclosure 3, a loudspeaker mechanism 4, and a sound guide 5.

The enclosure 3 is rectangular in shape, confines an enclosure space 30, and has a front wall 31 formed with a large speaker aperture 311 and a small sound port 312 vertically spaced apart from each other.

The loudspeaker mechanism 4 is acoustically mounted in the enclosure 3 for radiating sound. In particular, the loudspeaker mechanism 4 is disposed inside the enclosure space 30, is mounted on the front wall 31, and is registered with the speaker aperture 311. In this embodiment, the loudspeaker mechanism 4 is retained in the speaker aperture 311. The loudspeaker mechanism 4 is to be connected to a signal source (not shown), and is driven by audio signals from the signal source to produce sound waves that are transmitted forwardly. Since the loudspeaker mechanism 4 is conventional in construction, and since the feature of the present invention does not reside in the specific construction of the loudspeaker mechanism 4, further details of the same are omitted herein for the sake of brevity.

The sound guide 5 is mounted in the enclosure space 30 of the enclosure 3, and includes a sound-collecting cover 51 and a sound duct 52. The sound-collecting cover 51, which is made of plastic in this embodiment, has a concave inner surface 510 that covers a back side of the loudspeaker mechanism 4, a front periphery 511 that is mounted on the front wall 31 (such as with the use of fasteners) and that surrounds the loudspeaker mechanism 4, and a rear end 512 opposite to the front periphery 511. The inner surface 510 of the sound-collecting cover 51 cooperates with the front wall 31 to confine a sound-collecting space 50 for collecting back waves generated by the loudspeaker mechanism 4. The sound duct 52 has a first end 521 connected to the rear end 512 of the sound-collecting cover 51 and in spatial communication with the sound-collecting space 50, and a second end 522 connected to the front wall 31 of the enclosure 3 at the sound port 312 and in spatial communication with an exterior of the enclosure 3. In this embodiment, the sound duct 52 is flexible and tortuous to facilitate its assembly inside the enclosure 3. Preferably, the sound duct 52 is a flexible plastic tube that is bendable. However, the sound duct 52 may be a rigid tortuous plastic tube in other embodiments of this invention.

During operation, the back waves generated by the loudspeaker mechanism 4 will be guided to the exterior of the enclosure 3 through the sound-collecting cover 51 and the sound duct 52 of the sound guide 5. The intensity of the back waves is diminished as the latter propagates in the tortuous sound duct 52. As a result, back wave interference is effectively reduced in the loudspeaker device of this invention so as to improve sound output quality.

In practice, the dimensions of the sound-collecting cover 51, the connection between the sound-collecting cover 51 and the sound duct 52, and the size and shape of the sound duct 52 may be adjusted to optimize the reduction in back wave interference. Moreover, since the back waves generated by the loudspeaker mechanism 4 are transmitted through the sound guide 5, other components, such as a wireless signal receiver for a wireless microphone, a sound recording device, a compact disc player, a cassette tape recorder/player, a digital sound file player, a sound volume control mechanism, etc., may be optionally mounted in the enclosure space 31 of the enclosure 3 to improve functionality of the loudspeaker device.

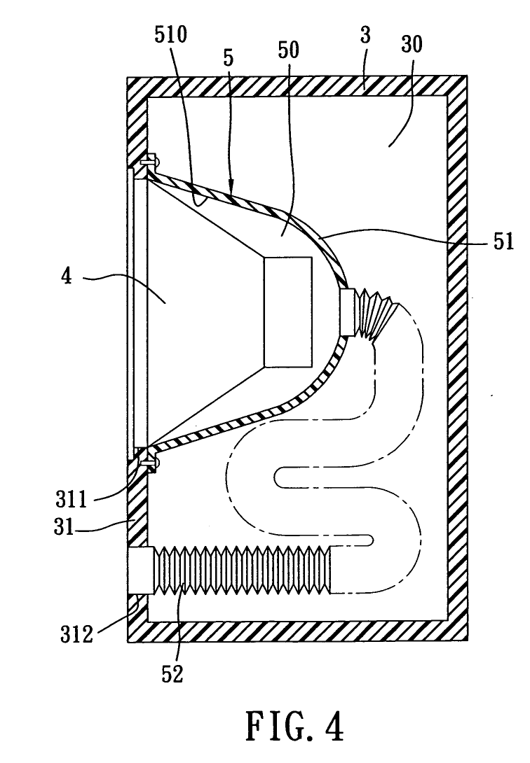

Referring to FIG. 4, the second preferred embodiment of the loudspeaker device according to this invention is shown to differ from the previous embodiment in that the sound duct 52 is in the form of a bellows tube.

In sum, by means of the sound guide 5, back wave interference can be effectively reduced in the loudspeaker device of this invention so as to improve sound output quality. Moreover, the sound-collecting cover 51 and the sound duct 52 of the sound guide 5 are less costly to fabricate and install as compared to the lining of sound-absorbing material used in the conventional loudspeaker device.

While the present invention has been described in connection with what is considered the most practical and preferred embodiments, it is understood that this invention is not limited to the disclosed embodiments but is intended to cover various arrangement included within the spirit and scope of the broadest interpretation so as to encompass all such modifications and equivalent arrangements.

What is claimed is:

1. A loudspeaker device comprising:
an enclosure;
a loudspeaker mechanism acoustically mounted in said enclosure for radiating sound; and
a sound guide mounted in said enclosure and including a sound-collecting cover that covers a back side of said loudspeaker mechanism, and a sound duct having a first end in spatial communication with said sound-collecting cover and a second end connected to said enclosure and in spatial communication with an exterior of said enclosure.

2. The loudspeaker device as claimed in claim 1, wherein said enclosure has a front wall formed with an aperture and a sound port, said loudspeaker mechanism being mounted on said front wall and being registered with said aperture, said sound-collecting cover having a front periphery that is mounted on said front wall and that surrounds said loudspeaker mechanism, said sound-collecting cover further having a rear end opposite to said front periphery, said first end of said sound duct being connected to said rear end of said sound-collecting cover, said second end of said sound duct being connected to said front wall at said sound port.

3. The loudspeaker device as claimed in claim 2, wherein said sound-collecting cover has a concave inner surface that covers said back side of said loudspeaker mechanism.

4. The loudspeaker device as claimed in claim 1, wherein said sound duct is flexible and tortuous.

5. The loudspeaker device as claimed in claim 4, wherein said sound duct is a flexible plastic tube.

6. The loudspeaker device as claimed in claim 4, wherein said sound duct is a bellows tube.

7. The loudspeaker device as claimed in claim 1, wherein said sound duct is a flexible plastic tube.

8. The loudspeaker device as claimed in claim 1, wherein said sound duct is a bellows tube.
